(19) United States
(12) Patent Application Publication
(10) Pub. No.: US 2008/0173470 A1
(43) Pub. Date: Jul. 24, 2008

(54) Combined Solderable Multi-Purpose Surface Finishes on Circuit Boards and Method of Manufacture of Such Boards

(75) Inventors: Michael Barbetta, Avondale, AZ (US); Donna Rae Fawcett, St. George, UT (US)

Correspondence Address: Donna R. Fawcett, 1659 S. Agate Circle, St. George, UT, 84790, US

(73) Assignee: Michael Barbetta, Avondale, AZ (US)

(21) Appl. No.: 11/163,034

(22) Filed: Oct. 3, 2005

(51) Int. Cl. H05K 1/09

(52) U.S. Cl. 174/257

(57) ABSTRACT

A circuit board, in one embodiment a printed wiring board (PWB); in a second embodiment a substrate for an ASIC (Application Specific Integrated Circuit) or Chip Carrier; and a method of manufacturing the same. In one embodiment, the PWB, ASIC or Chip Carrier includes: (1) a substrate having a conductive trace located thereon and (2) a combined, multi-purpose surface finish utilizing an electroless or electrolytically deposited nickel under-plate finished with a coating of an organic solderability preservative (OSP) and is located on at least a portion of the conductive areas (trace, pad, fingers, etc), which forms both a non-contact finish and a contact finish for the PWB, ASIC or Chip Carrier.

### BRIEF DESCRIPTION OF DRAWINGS

For a more complete understanding of the present invention, reference is now made to the following descriptions taken in conjunction with the accompanying drawings, in which:

FIGS. 1 through 3 illustrate the cross section of a PWB or other circuit board, constructed according to the claims of this invention.

FIGS. 2 through 3 illustrate the Process Sequence of the nickel deposit formed in an electroless mode, with the OSP coating over the nickel.

### DETAILED DESCRIPTION

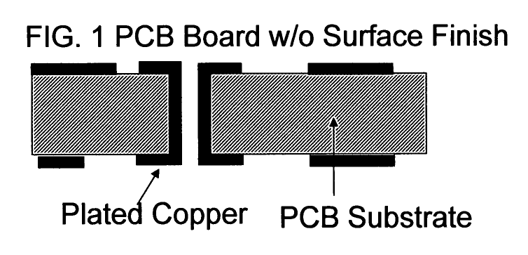

FIG. 1 illustrates a PWB having a substrate, normally a material, such as glass reinforced epoxy, on which numerous layers may be formed. While the substrate illustrated in this embodiment is composed of glass reinforced epoxy, those skilled in the art will realize that the substrate may be composed of any substrate materials, including epoxies, polyimides, fluorinated polymers, ceramics, polyesters, phenolics, and aramide paper. A base copper laminate or similar laminate material is place over the entire substrate. Following the application of the base copper laminate, a photo resist layer is then applied on top of the base copper laminate. The photo resist layer is then exposed to ultraviolet light which exposes the circuit trace pattern thereon and the circuit trace pattern is formed as seen in FIG. 1. Using an acid copper plating method, an electrolytic copper plate is formed in the opening created by the photo resist, and on top of the base copper laminate. However, other types of copper, or similar material, may also be used.

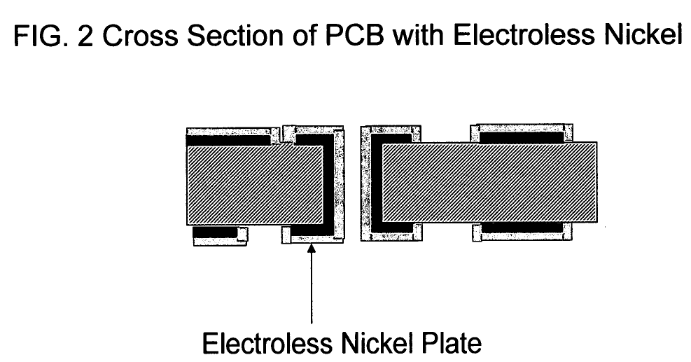

Next, as shown in FIG. 2, a nickel layer (nickel under-layer) is plated within the opening, and on top of the electrolytic copper plate, by conventional deposition processes. The nickel layer is placed upon the electrolytic copper plate to prevent oxidation of the copper and to give additional hardness to the surface finish (prevent the problem of having a soft metal deposit). Nickel, like copper, is known to oxidize and produce nickel oxide, but contrary to copper oxide, nickel oxide does not creep along the surface. Nickel's tendency to produce nickel oxide is further reduced when the OSP is applied over nickel. It should also be understood that materials similar to nickel such as nickel alloys may be used.

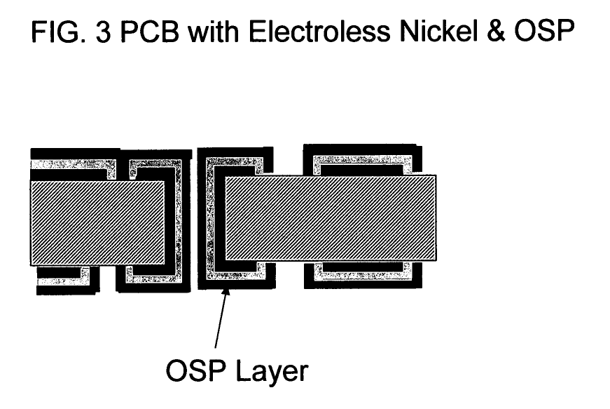

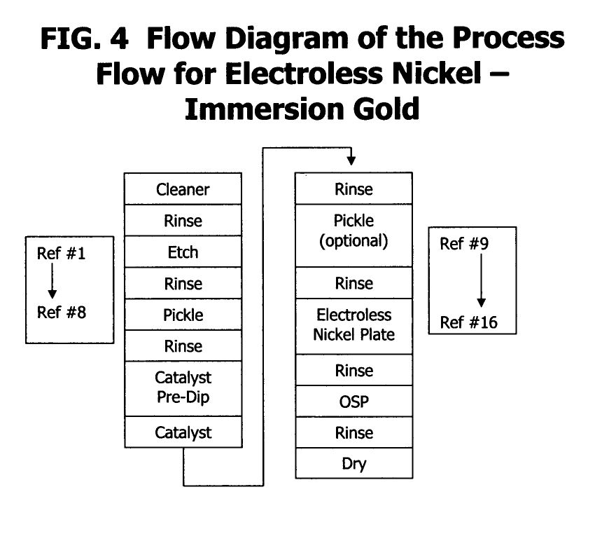

Referring next to FIG. 3, a layer of OSP is placed over the nickel layer (Ref. FIG. 2), which is on top of the electrolytic copper plate (Ref. FIG. 1). The OSP replaces the immersion gold or electrolytic gold plating process present in conventional processes. The organic solderability preservative (OSP) may be any of the types: R-substituted triazole, imidazole, or R-substituted imidazole that would act as a nitrogen donor to prevent oxidation and passivation of the nickel plate.

One major advantage that any electrolytically plated nickel under-plate provides in PWB manufacturing is its use as an etch resist replacement for tin or tin-lead. When used in this manner, the nickel under-plate may now be used as a multi-purpose finish for both non-contact and contact finishes. The use of a nickel under-plate not only removes lead from the surface finishing production area, a major waste treatment expense, but the cycle time becomes much shorter as the plating and subsequent stripping of the etch resist material is eliminated. Fabrication time is substantially shortened because about 50% of the processing steps can be eliminated.

The nickel under-plate and OSP coating, as defined herein, has a characteristic of low porosity. Low porosity minimizes formation of corrosion products of exposed copper which in turn, preserves conductivity, solderability and wire bondability of the surface.

Likewise, the nickel under-plate with OSP coating provides superior wear resistance, excellent diffusion/migration barrier properties, high thermal stability and good co-planarity. All these properties make the nickel under-plate with the OSP coating a good finish for both non-contact and contact areas.

For electrolytic nickel plating applications, after the nickel under-plate deposition, the photo resist layer is stripped. This uncovers portions of the base copper laminate that are to be removed. The exposed base copper laminate, which was formerly covered by the photo resist, is etched away using conventional copper etch processes, which results in the circuit traces as illustrated in FIG. 1. The nickel under-plate acts as an etch resist to a portion of the copper circuit traces. What is left after the resist strip and copper etch is a substrate, covered by a copper circuitry.

The final, required step of the process, comprises the function of applying a solder mask to the substrate. A solder mask is applied to prevent solder bridges from forming during the assembly performed by the board user.

One concern is that after using the nickel under-plate as an etch resist, there may be exposed copper circuitry on the circuit side walls. The exposed copper circuitry will be covered with a protective coating, in the additional step of adding the organic solderability preservative (OSP). This coating will be applied using a conventional process.

FIG. 2 illustrates that the nickel under-plate process as applied will prevent copper creep. As an alternative to an electrolytic nickel plate, an electroless nickel under-plate can be applied. The electroless nickel under-plate is formed using a reduction process and covers the remaining copper circuitry. Using an electroless nickel under-plate provides more even thickness distribution, than when using an electrolytic nickel under-plate.

### FIG. 4.

### Electroless Nickel/OSP

FIG. 4. is a flow chart showing the various steps that might occur in the embodiments just discussed above. As shown, one embodiment may further include a clean copper laminate/substrate step (Ref #1) followed by a rinse (Ref #2), followed by a micro-etch copper laminate/substrate step (Ref #3), followed by a rinse (Ref #4) and an optional (depending on the type of etch utilized) acid dip (pickle) copper laminate/substrate step (Ref #5).

Following another rinse (Ref #6), the catalyst pre-dip (Ref #7) and the catalyst (Ref #8), additional rinsing (Ref #9) and an optional second pickle step (Ref #10), rinse step (Ref. #11), electroless nickel plating is applied (Ref #12). After rinsing (Ref #13), OSP is applied (Ref #14) with a final rinse step (Ref #15) and dry (Ref #16).

### FIG. 4. Process Sequence Details:

### Clean Ref.#1

The cleaner is used to clean dirt and foreign debris from the printed circuit board, and to remove any oxides or oils. It can be made up of, but not limited to: water, a weak organic or Lewis acid, usually phosphoric (H₃PO₄), sometimes a polar solvent, such as methyl alcohol, and a surfactant.

### Rinse Ref.#2

Rinsing is achieved using a double or triple rinse, or whatever is adequate to remove the cleaner residue (s) and foreign matter from the printed circuit boards.

### Etch (Ref #3)

Usually referred to as a microetch. The microetch is designed to create a micro-roughened surface on the copper deposit to assure improved adhesion of subsequent additives or coatings.

Any of several varying chemistries dissolved in water can be used to etch≈30-60 pin of copper from the surface of the printed circuit board:

sodium, potassium, or ammonium persulfate (S₃O₄⁻²) with or without some sulfuric acid (H₂SO₄) added. sodium or potassium mono-oxysulfate (OS₃O₄) with or without some sulfuric acid (H₂SO₄) added.

sulfuric acid (H₂SO₄) with hydrogen peroxide (H₂O₂), using a stabilizer to slow the evaporation of the peroxide molecule; usually, but not limited to, methyl sulfonic acid (HCH₃SO₃).

### Rinse (Ref #4)

Rinsing is achieved using a double or triple rinse, or whatever is adequate to remove the microetch residue(s) and foreign matter from the printed circuit boards.

### Pickle (Ref #5)

This is a dilute acid, usually sulfuric (H₂SO₄) or hydrochloric (HCl) in concentrations ranging for 1-20%. Its function is to neutralize any microetch remains, and to remove or prevent the formation of oxides.

### Rinse (Ref #6)

Rinsing is achieved using a double or triple rinse, or whatever is adequate to remove the acid residue(s) and foreign matter from the printed circuit boards.

### Catalyst Pre-Dip (Ref #7)

This step is used without a rinsing afterwards, and primary function is to maintain the acidity and specific gravity of the catalyst step through drag-in of its chemistry. It is mainly comprised of a weak concentration of a “like” acid of the catalyst or acid salt.

### Catalyst (Ref #8)

A palladium or ruthenium based catalyst—as sulfate or chloride (PdSO₄, PDCl₂, Ru₂(SO₄)₃, RUCl₃)—is employed to catalyze the surface of the copper and aid in supplying a more uniformed, active base for the application plating of the electroless nickel layer. The catalyst is dissolved in a solution containing a “like” acid—either sulfuric (H₂SO₄) or hydrochloric (HCl)—or acid salt, in concentrations ranging up to 50%. Sometimes urea or its acid is added in small concentrations to lower the volatility of the bath chemicals.

### Rinse (Ref #9)

Rinsing is achieved using a double or triple rinse, or whatever is adequate to remove the catalyst residue (s) and foreign matter from the printed circuit boards.

### Pickle *Optional Step (Ref #10)

This is a dilute acid, usually sulfuric (H₂SO₄) or hydrochloric (HCl) in concentrations ranging for 1-20%. Its function is to prevent the formation of oxides.

### Rinse (Ref #11)

Rinsing is achieved using a double or triple rinse, or whatever is adequate to remove the acid residue(s) and foreign matter from the printed circuit boards.

### Electroless Nickel Plate¹ (Ref #12)

The electroless nickel plating layer is used as the primary solderable surface and consists of the chemistry mentioned below. The plating thickness can vary immensely to suit the needs of the applicable specification, but frequently conforms to thicknesses of 125-250 μin.

### Rinse (Ref #13)

Rinsing is achieved using a double or triple rinse, or whatever is adequate to remove the nickel plating residue(s) and foreign matter from the printed circuit boards.

Organic solderability preservative (OSP)² (Ref #14) A final coating of a solderability preservative is applied to maintain the solderable surface of the nickel underplate for an extended period of time (as much as 1-1.5 years), and is generally destroyed in the later soldering operations. The chemical makeups of this bath are listed below.

Application thicknesses after drying range from 0.1 μm to ≧0.5 μm.

### Rinse (Ref #15)

Rinsing is achieved using a double or triple rinse, or whatever is adequate to remove the OSP residue(s) and foreign matter from the printed circuit boards.

### Dry (Ref #16)

Drying is used as the last step to dry the OSP coating, as well as the complete printed circuit board.

The electroless nickel¹ makeup consists of, but is not limited to:

nickel sulfate [NiSO₄]—the source of nickel metal
Lead (as metal) [Pb]—the primary stabilizer
Thiourea [(NH2)2CS]—the secondary stabilizer and accelerator
sodium hypophosphite [Na₂H₂PO₂]—the chemical reducing agent Water adjusted to a pH range of 4.0 to 5.5-pH is lowered by the addition of sulfuric acid (H2SO4); and raised with the addition of nickel carbonate (NiCO3-2NiOH2).

The standard electroless nickel reduction reaction is well known as:

3Na₂H2PO2+3H2O+NiSO4 goes to 3NaH2PO3+H2SO4+2H2+Ni

The organic solderability preservative² makeup consists of water, a benzotriazole; or aliphatic or aromatic substituted triazole; or imidazole; or an aliphatic or aromatic substituted imidazole. The concentrations can vary to accommodate the application of the needed thickness and density of the final overcoat of the electroless nickel plate. As a rule, water is used as the solution.

As a result of the discussions above, the use of a nickel under-plate with an OSP coating as a multi-purpose PWB, ASIC and Chip Carrier finish on both non-contact circuits and contact areas maintains or even improves the required material properties, and achieves considerable cost saving. Cost saving is achieved through cheaper deposit material, and improved finish performance.

Although the present invention has been described in detail, those skilled in the art should understand that they can make various changes, substitutions and alterations herein without departing from the spirit and scope of the invention in its broadest form. The solderability achievable with a combined nickel and OSP deposit in printed circuit applications has been found to exceed that achievable with prior art nickel-gold plating processes such as described in U.S. Pat. No. 5,235,139 and exceeds that achievable with other immersion deposits. The processes of the current invention yield surfaces which are very solderable under adverse conditions. The surfaces are wire bondable.

Both the electroless or electrolytic nickel chemistries and the organic solderability coating used would be existing available products. The process however would be unique in that it would employ both baths in combination to prevent subsequent oxidation and/or passivation of the nickel layer.

This process would eliminate both the ability of the system to make black pad and other similar plating separation problems in the ENIG and related immersion plating processes, and solve the problem of having a soft metal deposit by plating a hard nickel plate.

### TECHNICAL FIELD OF THE INVENTION

This invention relates generally to a method of treating a surface in which treatment enhances the solderability of the surface.

The present invention is directed, in general, to circuit boards and substrates and, more specifically, to a combined, multi-purpose finish for printed wiring boards (PWBs), substrates, chip carriers, ASICs and the like, and a method of manufacture of such PWBs, Substrates, Chip Carriers, and ASICs.

### BACKGROUND OF THE INVENTION

Printed Wiring Board (PWB), ASIC and Chip Carrier manufacturing processes are changing at a rapid rate because of the increasing demand for enhanced performance. The demand for enhanced performance is due to higher circuit densities, and increase in design complexities and an increase in the cost of environmental compliance. Many types of surface finishes are used on PWBs, ASICs and Chip Carriers. As stated by Abys et al. in U.S. Pat. No. 6,534,192, whose teachings are incorporated herein by reference, surface finish selection is generally dependent on the final requirements. Surface circuits usually include copper and copper alloy materials that should be coated to provide good mechanical and electrical connection with other devices in the assembly.

Typically, the coating on the circuits is called the surface finish. The circuits include non-contact areas and contact areas. The finish applied to the non-contact areas is called non-contact finish and the finish applied to the contact areas is called contact finish. The non-contact areas included wire bonding areas, chip attach areas, soldering areas and other non-contact areas. Both non-contact and contact finishes must meet certain requirements. Non-contact finish requirements include good solderability, wire bonding performance, and high corrosion resistance. Contact finish requirements include high conductivity, wear resistance and corrosion resistance. Historically, different coatings have been used for non-contact and contact finishes.

Some typical non-contact finishes include: hot air solder level (HASL), electroless nickel with immersion gold coating (ENIG), organic solderability preservative (OSP), immersion silver, and organometallic, such as organo-silver, which is an immersion silver formulated with OSP (OSP/Ag).

The organic is co-deposited with the silver.

Good solderability can be ensured by coating the surface with a pre-coating of solder. This is typically performed by a process called hot air solder leveling or through some type of plating process. Hot air solder leveling may cause a high rate of defects due to solder shorts on fine line circuitry. The amount of solder deposited on pads and other features varies widely and does not meet the requirement of coplanar surfaces today.

A typical contact finish may include an electrolytic nickel coating with an electrolytic hard gold layer (gold-nickel or gold-cobalt alloys with nickel or cobalt less than 0.3% by wt.) on top. To coat any of the above non-contact finishes on the circuits and to coat the finish on the contact areas requires considerable processing steps (20+ steps).

U.S. Pat. No. 5,235,139 (Bengston, et. Al.), whose teachings are incorporated herein by reference, proposes a method for achieving a precious metal coating over the electroless nickel-boron. Also, U.S. Pat. No. 4,940,181 (Juskey, Jr. et. Al.) has a similar process of plating electroless copper, followed by electrolytic copper, followed by nickel, followed by gold as a solderable surface.

A contact finish like electrolytic nickel/gold must be applied on the contact areas after the non-contact finish is coated. The contact finish has good conductivity and high wear resistance. However, it cannot be used as a non-contact finish due to its poor solderability and wire bondability. To apply this contact finish to the board selectively adds costs.

U.S. Pat. No. 5,693,364 (Kukanskis) whose teachings are incorporated herein by reference, reveals a process for selectively imaging a printed circuit board using nickel plate, rather than copper plate. Any of the surface finishes generally available are suggested for use, including OSP. However, Kukanskis does not claim that any of the surface finishes over the nickel traces is better than another. In the quest for the perfect surface finish, the industry has experienced some success with each new surface finish. However, over time, there have been issues and shortcomings of each of these processes. For example, electroless nickel-immersion gold (ENIG) suffers from an industry-wide defect known as “black pad”. Black pad is a galvanic hypercorrosion of the nickel deposit by the overlying gold deposit. Organic solderability preservatives (OSP) are subject to assembly defects due to its thin coating thickness coupled with the soft, easily oxidized copper plate underneath. Organo-silver deposits have “outgassing” issues during assembly, resulting to the coined phrase “champagne bubble voids”. When the organo-silver deposit is greater than 5 microinches, the organic material does not entirely burn off during assembly and that organic material remaining behind, forms gas pockets in the silver deposit, resulting in weak solder joints.

U.S. Pat. No. 5,935,640 (Ferrier), whose teachings are incorporated herein by reference, although not wishing to be bound by theory, believed that the first silver (or any other) immersion coating is inherently porous and therefore may leave some pathways to the underlying (copper) surface exposed. In other schemes of combined metal depositions, the suggested second immersion coating is applied, these more noble metal ions have an access not only to the intermediate metal layer, but also to the base layer via the pores. Since the difference between the standard red-ox potential of the base and the top layer is greater than that between the base and intermediate layers, the immersion reaction will proceed with a much faster rate in the pores (i.e. on any exposed base metal). The second metal will begin to corrode the base metal through the pores, resulting in subsequent solderability issues.

### SUMMARY OF THE INVENTION

To address the issues and shortcomings of the prior art, the present invention provides a combined, multi-purpose finish for a PWB, ASIC or Chip Carrier and a method of manufacturing the same. In one embodiment, the PWB, ASIC or Chip Carrier includes: (1) a substrate having a conductive trace located thereon and (2) a combined, multi-purpose finish including electroless or electrolytically deposited nickel coated with an OSP, and is located on at least a portion of the conductive trace, which forms both a non-contact and a contact finish for the PWB, ASIC or Chip Carrier.

This process introduces the broad concept of employing a nickel deposited coated with an OSP, as a combined, multi-purpose finish for PWBs, ASICs, Chip Carriers and any other device with a copper circuit. The traces preferably comprise copper. However, other conductive materials may be used, such as copper alloys, aluminum, nickel, silver, gold, platinum or their alloys, for the conductive traces.

In one embodiment, the non-contact finish coats at least a portion of a non-contact area. In a related embodiment, the contact finish coats at least a portion of a contact area. In another embodiment, the nickel with OSP coating is located on all of the conductive traces.

U.S. Pat. No. 6,534,192 (Abys et al.), whose teachings are incorporated herein by references, states that in another embodiment, nickel may be applied, using conventional deposition processes, under the palladium alloy, forming a nickel underlayer. Abys states that this nickel under-layer is optional to that process and can be omitted. Since the palladium alloy process is an immersion process, it still suffered from the same problems as other immersion chemistries. The nickel under-layer is suggested to seal the copper and to make the palladium alloy coating more effective over time. The essence of this invention is that it combines the goodness of the nickel under-layer, without the problems and expensive of another immersion or plated metal layer to prevent oxidation of the nickel. The OSP surface finish, over the nickel deposit, is the simplest of all of the combinations of surface finishes that addresses issues of oxidation, porosity, and solderability of non-contact and contact surfaces.

In another embodiment of the present invention, the non-contact areas comprise surface mount pads, wire bond pads, solder pads or interconnections. Interconnections are defined as circuit traces, plated through holes and micro-vias.

The substrate may comprise various materials that are typically used for PWB, ASIC and Chip Carrier fabrication. Examples of these materials contain epoxies, polyimides, fluorinated polymers, ceramics, polyesters, phenolics and aramide paper.

Those skilled in the art should realize that equivalent constructions do not depart from the spirit and scope of the invention in its broadest form.

The electroless nickel plating process and sequence is widely employed, regularly however, with an immersion gold overplate to protect the solderability of the nickel. And organic solderability preservatives are also widely used, almost always as a “stand alone” practice over the primary plated copper, to protect the solderability of the copper. This proposed application process marries both chemical processes to create a unique method of assuring the activation and solderability of the electroless nickel over time, without using gold or any other metal overplate(s) which are prone to galvanic corrosion and hypercorrosion issues between the nickel layer and the final plated metal layer.

What is claimed is:

1. A printed wiring board (PWB), ASIC or Chip Carrier, comprising: a substrate having at least one conductive trace thereon, said conductive trace consisting of:
A copper or copper alloy laminate layer located on said substrate, defining a pattern of said trace on said substrate;
An intermediate copper layer located on said laminate layer; and
A combined, multi-purpose finish consisting of nickel (electroless or electrolytically deposited) under-plate located on said intermediate layer; and an organic solderability preservative (OSP) deposited on top of the under-plate nickel, that forms both a non-contact and a contact finish for said PWB, ASIC or Chip Carrier.

2. The PWB, ASIC or Chip Carrier as recited in claim 1 wherein said nickel deposit includes nickel and any other ingredients.

3. The PWB, ASIC or Chip Carrier as recited in claim 1 wherein said nickel deposit may or may not be an etch resist layer.

4. The PWB, ASIC or Chip Carrier as recited in claim 1 wherein said conductive trace is located on at least a portion of a non-contact area.

5. The PWB, ASIC or Chip Carrier as recited in claim 4 wherein said non-contact area is selected from the group consisting of:
a surface-mount pad,
a wire bond pad,
a solder pad, and
an interconnection.

6. The PWB, ASIC or Chip Carrier as recited in claim 1 wherein said conductive trace is located on at least a portion of a contact area.

7. The PWB, ASIC or Chip Carrier as recited in claim 1 wherein the source of the nickel metal consists of, but is not limited to: nickel sulfate [NiSO₄].

8. The PWB, ASIC or Chip Carrier as recited in claim 1 wherein the source of OSP consists of, but is not limited to R-substituted triazole, imidazole, or any R-substituted imidazole that would act as a nitrogen donor to prevent oxidation and passivation of the nickel plate.

9. The PWB, ASIC or Chip Carrier as recited in claim 7 wherein the nickel would be present in an alloy in an amount of 5% or greater.

10. The PWB, ASIC or Chip Carrier as recited in claim 1 wherein said combined nickel and OSP finish is located on all of said conductive traces not covered by the soldermask.

11. The PWB, ASIC or Chip Carrier as recited in claim 1 wherein said substrate is comprised of a material selected from the group consisting of:
Epoxies;
Polyimides;
Fluorinated polymers;
Ceramics;
Polyesters;
Phenolics;
Aramide paper; or any other thermoset or thermoplastic resins applicable for PWB, ASIC or Chip Carrier use.
